(19) United States
(12) Patent Application Publication
(10) Pub. No.: US 2007/0187070 A1
(43) Pub. Date: Aug. 16, 2007

(54) Heat sink with slant fin

(75) Inventor: Hu-Sung Chang, Taipei (TW)

Correspondence Address: RABIN & Berdo, PC, 1101 14TH STREET, NW, SUITE 500, WASHINGTON, DC, 20005, US

(73) Assignee: ASUSTEK COMPUTER INC., Taipei (TW)

(21) Appl. No.: 11/656,522

(22) Filed: Jan. 23, 2007

(30) Foreign Application Priority Data
Feb. 14, 2006 (TW) 095104922

(51) Int. Cl. H05K 7/20

(52) U.S. Cl. 165/80.3; 361/704; 361/697

(57) ABSTRACT

A heat-sink with slant fins is provided. The slant fin may change the area of the cross-section along the direction of winds blowing. Due to the fact that the area is decreased, the flow speed increases. That solves the retained hot air resulted from a remote distance from the fan.

### BACKGROUND OF THE INVENTION

1. Field of Invention

The invention relates to a heat sink applied to electrical devices. More particularly, the invention relates to a heat sink with slant fin which enables to adjust air flow speed.

2. Related Art

With the rapid development of technology, calculating speed of chipsets such as a central processing unit (CPU) is getting faster than before. However, the instant heat from this rapid speed raises temperature simultaneously. Therefore, a heat sink is offered in a chipset i.e. a CPU, northbridge/southbridge chips on a motherboard, graphic chips on a display card and so forth for lowering temperature to a normal working temperature range.

The chipsets of computer systems mentioned above are divided into two parts: one is a chip on a motherboard such as a CPU, northbridge/southbridge chips; the other is a chip on an interface card such as graphic chips on a display card. Facing a situation that the tech of a heat sink does not keep pace with the advance of a chipset's calculating speed, a heat dissipation function for a heat sink is being tested. Even though a big and powerful heat sink is easily offered in a CPU and northbridge/southbridge chips on a motherboard due to an enough space between a motherboard and a case, an interface card such as a chip on a display card still faces a heat dissipation problem due to a limited space between those interface cards for further installment. Thus, hot air must remain stationary and lower the efficiency of heat dissipation in the meantime. Besides, with a miniature trend for a case size and a computer system, a heat sink bundled to a chip on a motherboard faces the same dilemma of heat dissipation.

In general, manufacturers focus on two aims for bettering a heat dissipation function of heat sink: wind speed of a fan and fins of a heat sink. As for a fan improvement, it relates to a specific design for a fan configuration, a bearing improvement i.e. an oil bearing and a fluid bearing, or an increase of motor-rotation speed. Speaking of an improvement for fins of a heat sink, it primarily relates to a material selection of heat-sink fins and also their arrangement, i.e. parallel and vertical arrangements and so forth. All in all, the aims mentioned above come from Mechanics improvement. Honestly speaking, in such a mature technical field of mechanics, there is little room left to improve. For instance, adopting a fluid bearing instead of a rolling one enables to decrease a friction. This leads to little improvement for heat dissipation but an increase of R&D costs.

Regarding the most competitive arrangement design for heat-sink fins, either parallel or vortex is the common arranging ways at present. In addition, key manufacturers improve the technology in this manner to smooth a fluid filed and let air pass through heat-sink fins much rapidly. This thus results in a well effect of heat dissipation. Nevertheless, this kind of design is aimed at total improvement, not a heat sink itself.

### SUMMARY OF THE INVENTION

In view of the foregoing, an objective of the invention is to provide a heat sink with slant fins which relates to a basic structure improvement on a heat sink itself, thus bettering an effect of heat dissipation

The invention discloses a heat sink with slant fins where air is conducted into a heat sink, thus forming an air flow. The heat sink includes a heat sink body and a slant fin. The heat sink body has heat dissipation fins where the slant fin is installed. The slant fin scales down a cross-section which a fluid filed passes through in a direction of air flow. While flow speed along the direction of air flow is increasing, the hot air will not remain stationary in the end of the air flow. Hence, the effect of heat dissipation will increase.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a schematic view of a heat sink with slash fins according to the invention.

FIGS. 2A and 2B are schematic views of embodiment 1 of a heat sink with slant fins according to the invention.

FIGS. 3A and 3B are schematic views of embodiment 2 of a heat sink with slant fins according to the invention.

FIGS. 4A and 4B are schematic views of embodiment 3 of a heat sink with slant fins according to the invention.

### DETAILED DESCRIPTION OF THE INVENTION

The disclosed heat sink with slant fin is used to better a traditional layout of air flow given that weakening wind speed always causes a retained hot air in the end of air flow, thus resulting in insufficient effect of heat dissipation. In the meantime, this disclosed heat sink also suits every traditional heat sink type. In other words, the slant fin can be directly added-in and its related application is pretty board. To sum up, a heat sink body is installed with a fan which is used for blowing air into heat dissipation fins to form an air flow.

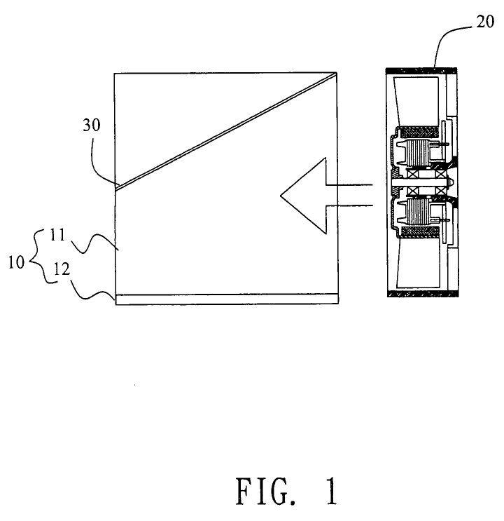

Referring to FIG. 1, a heat sink with slant fins includes a heat sink body 10, a fan 20 and slant fins 30. Moreover, the heat sink body 10 includes a base 11, plural heat dissipation fins 12. The fan 20 is installed in one side of the heat sink body 10. That is, the fan 20 is adjacent to one side of the heat dissipation fins 12 where air is forcibly conducted in and thus the heat from the heat dissipation fins 12 is pulled out. In a way of forcibly conducting air gets rise to an air flow, of which flow direction 21 reveals a left hand side as shown in FIG. 1. Of that, a layout of the slant fins 30 makes the air flow pass through a cross-section of the heat dissipation fins 12 which is then scaling down as shown in FIG. 1. In other words, the right side of cross-section is more than the left side. Furthermore, according to the Bernoulli's Equation, assuming that the air flow remains constant, a change of cross-section influences a flow speed. To be more specific, decreasing of cross-section size leads to an increase of a flow speed.

As a result, as shown in FIG. 1, there is an accelerating effect on the left hand side for a flow speed. In other words, as compared to the previous studied heat sink, a flow speed on the remote side will keep increasing. Of that, an increased range is in accordance with a variance of cross-section. That is, if a range of cross-section does not scale down too much, a flow speed will increase limitedly. In other words, a flow speed is possibly less than or similar to a near-side wind speed. On the other hand, if a cross-section scales down too much, a wind volume probably becomes insufficient and then causes a negative effect. Therefore, basically speaking, an optimal distance between the bottom side of the slant fins 30 and the base 11 should exceed one-third the height of the entire heat dissipation fins 12.

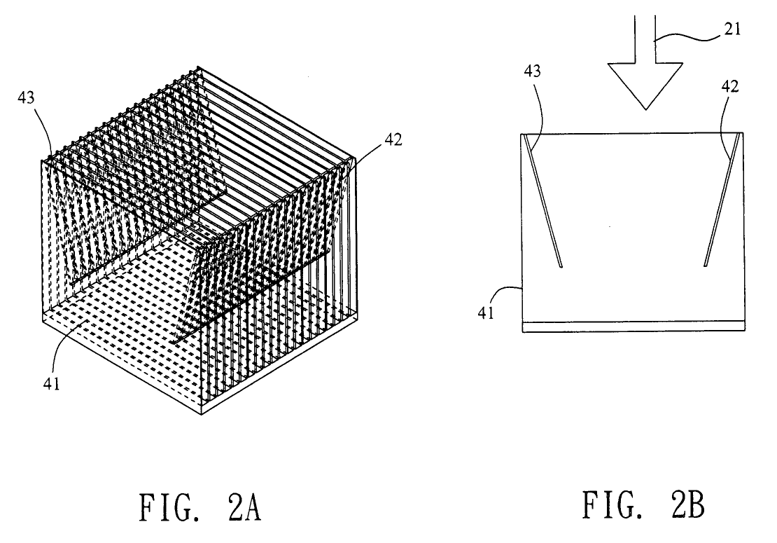

Referring to FIGS. 2A and 2B, the common type of heat-sink application in the market relates to the first embodiment. Heat dissipation fin 41 is in a parallel arrangement and it illustrates only one sheet of heat dissipation fin 41 with a parallel layout of plural lines. Likewise, it could be a single line separated into several smaller heat dissipation fins 41 in a parallel layout. Moreover, a fan is installed on the top side; that is, a flow direction 21 is downward. Hence, two sides are installed with slant fins 42 and 43 slanting to the bottom respectively in order to alter a flow speed. Therefore, from the side, the slant fins 42 and 43 meet orthogonally on the heat dissipation fin 41, making the cross-section of the flow direction 21 getting smaller in size, thus leading to accelerating effect at the bottom side. In addition, in accordance with the previous studied heat-sink, either a plate or a laminar metal adopted as one kind of material to produce the slant fins 42 and 43 are inserted and it can be used by the heat sink. Of course, it could be streamlined with the heat dissipation fins 41. The adopted materials are high-heat conductive metals such as coppers and aluminums, the same as those of the heat dissipation fin 41.

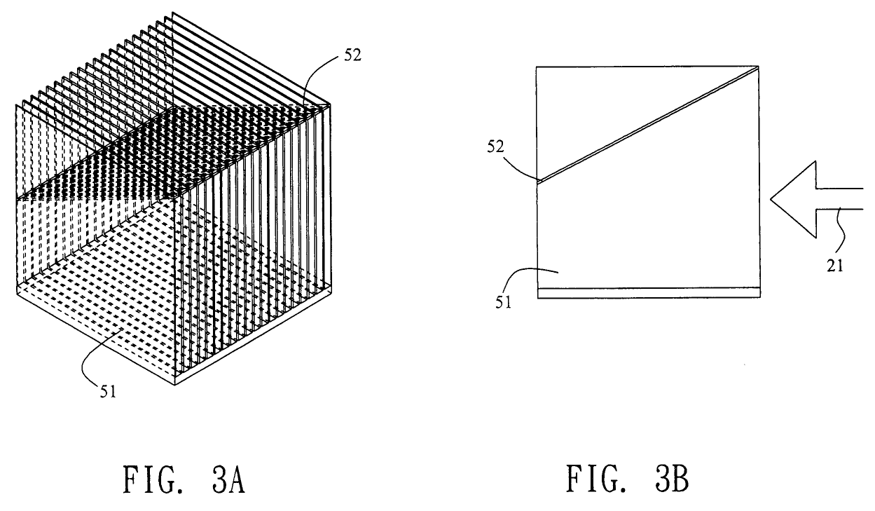

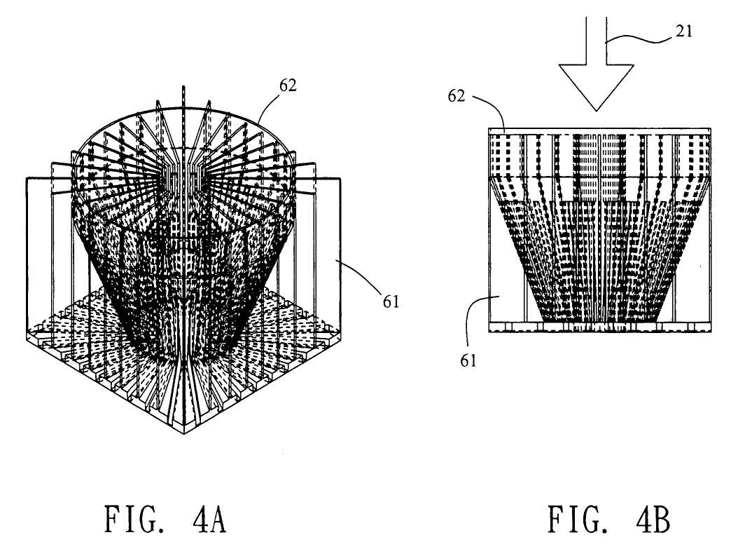

Referring to FIGS. 3A and 3B as the second embodiment, it relates to heat dissipation fins 51 in a parallel arrangement, but a flow direction 21 is sideward. In other words, a fan is installed on a side which is not shown in the figure. Therefore, a slant fin 52 is changed from a single side slanting to a diagonal one. As shown in FIGS. 4A and 4B, it relates to the third embodiment where heat dissipation fins 61 are in a radioactively outward scattered arrangement and a flow direction 21 is downward. Consequently, an outlook design of slant fins 62 is a cone where the bottom side of cross-section is less than the top side. Likewise, doing so attains the goal of increasing flow speed.

According to the above three embodiments, the result of quantitative analysis by using computer simulation is shown in the following table:

| | Original | Improved | Increased |
|---|---|---|---|
| | Temperature | Temperature | Efficiency |
| 1^{st} Embodiment | 78.41° C. | 73.64° C. | 12.34% |
| 2^{nd} Embodiment | 85.67° C. | 74.61° C. | 27.92% |
| 3^{rd} Embodiment | 89.48° C. | 82.45° C. | 14.81% |

Of that, an equation of increasing efficiency is listed below:

(Previous Studied Temperature−35)/(Improved Temperature−35)−1)*100%

The simulative data reveals a clear hike-up of heat dissipation efficiency. Simultaneously, with the unchanged structure of the previous studied heat sink, the heat dissipation efficiency increases too. Likewise, it suits every ordinary heat sink.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heat sink, wherein air is guided into to form an air flow, comprising:
a heat sink body, having a plurality of heat dissipation fins; and
at least one slant fin, installed in the heat dissipation fins to make the air flow scale down along a flow direction for increasing the flow speed of the air flow along the flow direction.

2. The heat sink of claim 1, wherein the slant fin is orthogonal with the heat dissipation fins.

3. The heat sink of claim 1, further comprising a fan installed in the heat sink body for guiding air to pass through the heat dissipation fins and forming the air flow.

4. The heat sink of claim 3, wherein the fin installed on the top side of the heat sink body.

5. The heat sink of claim 4, wherein the heat dissipation fins are in a radioactively outward scattered arrangement and the slant fin is orthogonal on the heat dissipation fins to form a cone surface.

6. The heat sink of claim 4, wherein the heat dissipation fins are in a parallel layout and further comprises another slant fin, the slant fins are orthogonal on the heat dissipation fins and also slant from two opposite top sides to another bottom sides respectively.

7. The heat sink of claim 3, wherein the fan is installed in one side of the heat sink body.

8. The heat sink of claim 7, wherein the heat dissipation fins are in a parallel layout,
